(19) United States
(12) Patent Application Publication
(10) Pub. No.: US 2007/0164729 A1
(43) Pub. Date: Jul. 19, 2007

(54) Verification of Performance Attributes of Packaged Integrated Circuits

(75) Inventors: Russell Paul Cowburn, London (GB); James David Ralph Buchanan, London (GB)

Correspondence Address: MCDONNELL BOEHNEN HULBERT & BERGHOFF LLP, 300 S. WACKER DRIVE, 32ND FLOOR, CHICAGO, IL, 60606, US

(73) Assignee: INGENIA HOLDINGS (UK) LIMITED, London (GB)

(21) Appl. No.: 11/623,633

(22) Filed: Jan. 16, 2007

Related U.S. Application Data
(60) Provisional application No. 60/761,870, filed on Jan. 25, 2006.

(30) Foreign Application Priority Data
Jan. 16, 2006 (GB) 0600828.8

(51) Int. Cl. G01R 31/28

(52) U.S. Cl. 324/158.1

(57) ABSTRACT

Packaged integrated circuits (ICs) of some types, such as processors, are graded and sold according to a performance scale, such as maximum specified clock speed, set by the manufacturer as a result of testing. As a record of this grading some part of the package, usually the upper surface, is marked with the specified performance attribute. However, criminal activity has developed where the packaging is relabelled to show a higher specification so the ICs can be fraudulently resold at a higher price. To address this problem, the invention envisages that manufacturers maintaining a product database for each packaged IC which logs not only the performance specification, but also a digital signature derived from a speckle pattern obtained from the packaging. Subsequently, any packaged IC can be rescanned to interrogate its speckle pattern and recompute the signature. The signature is then used to find the product in the database, whereby the originally specified performance attribute is retrieved. The fraud is then detectable. This method can be used to test products returned under a warranty claim, for example.

### BACKGROUND OF THE INVENTION

The present invention relates to verification of performance specifications of packaged integrated circuits (ICs).

Various technology solutions have previously been developed for marking goods as genuine in order to combat counterfeiting. Watermarking is one example of this kind of solution. Another type of solution measures a unique intrinsic physical property of the goods as a sort of fingerprint of each manufactured article. An example of this kind of solution is to use speckle patterns generated when light is scattered from the surface of an article, which may be paper, cardboard, plastic, metal or other kind of surface with a quasi-random surface profile [1-4]. For example, the speckle pattern measured from each manufactured article, or a signature calculated from the speckle pattern, can be stored in a database as a unique signature for the article. This signature can then be used for anti-counterfeiting enforcement, wherein a consignment of articles can be checked in the field to see if their speckle patterns are recognised or not, thereby defining them respectively as genuine or counterfeit.

In the field of semiconductor chips, the high level of technological difficulty and capital cost of manufacturing VLSI or ULSI circuits such as processors or memories means that conventional counterfeiting is not a significant problem. However, a different fraud has become prevalent.

Taking the example of processors, these are manufactured by a manufacturer such as Intel, AMD, ARM or Fujitsu, using a common process, and then only as a result of testing specified with a certain clock speed, and the packaged chip marked accordingly. For example, a 1 GHz processor is distinguished from a 500 MHz processor only as a result of its superior performance under test. Higher speed processors of a particular type are then sold at a premium.

The counterfeiting activity is as follows. Fraudsters buy lower speed processors, erase the markings on the packaging, remark them as higher speed processors and then re-sell them at a premium. Since under normal conditions the lower speed processors will initially work without fault at the higher speeds, this is virtually undetectable. It is only under extreme conditions of heat or humidity etc, or after natural degradation with time, that the lower speed processors start failing when being run at the higher speeds. When the processor fails, a warranty claim is made against the processor manufacturer. The processor manufacture then has to supply a replacement processor, and also suffers loss of reputation. The processor manufacturer cannot act to defend its reputation or resist the warranty claim, since it is unable to distinguish between, for example, a 500 MHz processor relabelled fraudulently as a 1 GHz processor and a genuine 1 GHz processor.

The fraud thus does not involve counterfeit goods, but genuine goods that are being relabelled fraudulently as having a higher performance specification than they should. The reason the scam works is that the performance specification is in practical terms unmeasurable after manufacture, even if significant resources are allocated. The performance specification is defined at the time of manufacture following highly complex testing. Moreover, the testing may be impossible to perform once the semiconductor chip has been packaged. For example any testing that directly probes intermediate parts of the integrated circuit situated away from the external contacts cannot be performed after packaging. Examples of such processes are OBIC (optical beam induced conductivity) or EBIC (electron beam induced conductivity) tests. Consequently, if the quality of the fraudulent relabelling is perfect, it effectively becomes impossible to identify the fraud.

### SUMMARY OF THE INVENTION

According to a first aspect of the invention there is provided a method for creating a product database for storing a record for each of a plurality of products, the products being packaged integrated circuits, the method comprising: providing an integrated circuit that has been attached to a package; providing a performance attribute for the integrated circuit that has been determined from testing of the integrated circuit; exposing a surface portion of the packaged integrated circuit to coherent radiation; collecting a set of data points that measure scatter of the coherent radiation from the surface portion; determining a signature from the set of data points; and augmenting the product database by storing the signature from the package together with the performance attribute in the record for that product.

The performance attribute may be clock speed, power consumption or some other variable performance attribute with a complex make up that follows from a wide variety of manufacturing process variables.

The surface portion scanned to collect the signature may be made of a variety of materials used for IC packaging. It may be made of a ceramic material (e.g. ceramic packaging material or lid such as alumina or beryllia), a metal (e.g. an exposed part of the lead frame, such as the pins, or lid, such as copper alloys, nickel-iron alloys), a plastics compound (e.g. plastics packaging material, or plastics moulding compound, or lid), or an epoxy compound (e.g. moulding compound).

The testing of the integrated circuit used to determine the performance attribute is carried out at least in part prior to packaging the integrated circuit. This aspect of the invention is particularly useful, since it may be that testing carried out prior to packaging cannot be reproduced after packaging, so that the signature becomes the only reliable permanent record of the ICs performance that can be subsequently obtained from the packaged IC.

To process batches of packaged ICs, said exposing and collecting may be performed by conveying successive packaged ICs past a beam of the coherent radiation.

According to a second aspect of the invention there is provided a method of determining a performance attribute of an integrated circuit ascribed to it at the time of manufacture as a result of testing, comprising: exposing a surface portion of the packaged integrated circuit to coherent radiation; collecting a set of data points that measure scatter of the coherent radiation from the surface portion; determining a signature from the set of data points; accessing a product database comprising a plurality of records of packaged integrated circuits, each record containing a signature obtained from a corresponding surface portion of the packaged integrated circuit at the time of manufacture together with the performance attribute; locating in the database a record for the packaged integrated circuit to be verified based on comparison between the determined signature and the signatures stored in the product database; and outputting the performance attribute of the packaged integrated circuit to be verified.

The method of the second aspect of the invention may further comprise: inputting the performance attribute of the packaged integrated circuit as shown by readable marks on the packaged integrated circuit; and determining if the performance attribute indicated by the readable marks is the same as the performance attribute according to the product database as a test of whether the readable marks are forgeries.

The readable marks may be machine readable marks (e.g. barcodes) and/or human readable marks (e.g. alphanumeric script marks).

The processor manufacturer can thus keep a full library of signatures at the manufacturing stage and then refer to these when dealing with warranty claims. Signature reading may also be of benefit to third parties, such as computer manufacturers buying in processors, or wholesalers, provided that the processor manufacturer grants access to its database.

### BRIEF DESCRIPTION OF THE FIGURES

Specific embodiments of the present invention will now be described by way of example only with reference to the accompanying figures in which:

FIG. 1A shows a SIP in side view;

FIG. 1B shows a DIP (DIL) in plan view;

FIG. 1C shows a QFP in plan view;

FIG. 2A is a schematic side view of an example of a reader apparatus;

FIG. 2B is a schematic perspective view showing how the reading volume of the reader apparatus of FIG. 2A is sampled;

FIG. 3 is a block schematic diagram of the functional components of the reader apparatus of FIG. 1;

FIG. 4A. shows fields of a sample database record;

FIG. 5 is a perspective view of the reader apparatus of FIG. 2A showing its external form;

FIG. 6 is a perspective view showing another example of a reader;

FIG. 7A shows schematically in side view an alternative imaging arrangement for a reader based on directional light collection and blanket illumination;

FIG. 7B shows schematically in plan view the optical footprint of a further alternative imaging arrangement for a reader in which directional detectors are used in combination with localised illumination with an elongate beam;

FIG. 8 is a microscope image of a plastic surface with the image covering an area of approximately 0.02×0.02 mm;

FIG. 9A shows raw data from a single photodetector using the reader of FIG. 2A which consists of a photodetector signal and an encoder signal;

FIG. 9B shows the photodetector data of FIG. 9A after linearisation with the encoder signal and averaging the amplitude;

FIG. 9C shows the data of FIG. 9B after digitisation according to the average level;

FIG. 10 is a flow diagram showing how a signature of an article is generated from a scan;

FIG. 11 is a flow diagram showing how a signature of an article obtained from a scan can be verified against a signature database;

FIG. 12 is a flow diagram showing how the clock speed marked on a packaged IC can be verified;

FIG. 13 is a flow diagram showing how the verification process of FIG. 11 can be altered to account for non-idealities in a scan;

FIG. 14A shows an example of cross-correlation data gathered from a scan;

FIG. 14B shows an example of cross-correlation data gathered from a scan where the scanned article is distorted;

FIG. 14C shows an example of cross-correlation data gathered from a scan where the scanned article is scanned at non-linear speed;

FIG. 15 is a schematic cut-away perspective view of a multi-scan head scanner; and

FIG. 16 is a schematic cut-away perspective view of a multi-scan head position scanner.

While the invention is susceptible to various modifications and alternative forms, specific embodiments are shown by way of example in the drawings and are herein described in detail. It should be understood, however, that drawings and detailed description thereto are not intended to limit the invention to the particular form disclosed, but on the contrary, the invention is to cover all modifications, equivalents and alternatives falling within the spirit and scope of the present invention as defined by the appended claims.

### DESCRIPTION OF PARTICULAR EMBODIMENTS

The invention specifically relates to scanning of packaged integrated circuits (ICs). In the following description, we often refer to the item being scanned using the generic term article. Examples of packaged IC types to which the invention is applicable are: microprocessors, graphics processors, memory chips, memory modules. Further, package types, which may be ceramic, plastic or other material type, to which the invention can be applied include:

1. Single In-L,ine Package (SIP)

2. Dual In-Line Package (DIP or DIL,)

3. Quad Flat Package (QFP)

4. Leaded or leadless Chip Carriers (LCCs)

5. Ball Grid Array (BGA)

6. Pin Grid Array (PGA)

7. Multi-Chip Modules (MCMs)

8. Single Inline Memory Modules (SIMMs)

9. Dual Inline Memory Modules (DIMMs)

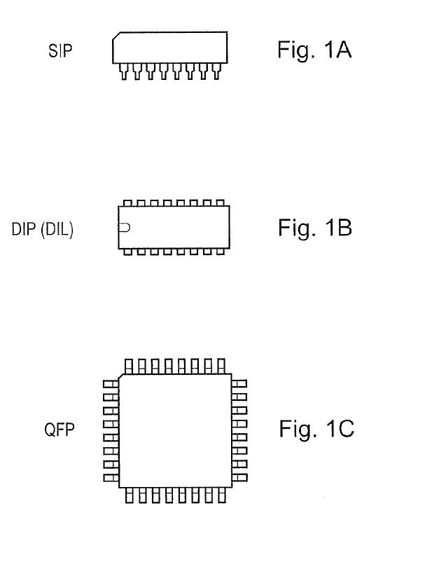

By way of example, FIG. 1A shows a SIP in side view. FIG. 1B shows a DIP (DIL) in plan view. FIG. 1C shows a QFP in plan view. Other standard package types mentioned above will be familiar to the skilled reader and are readily available in the literature.

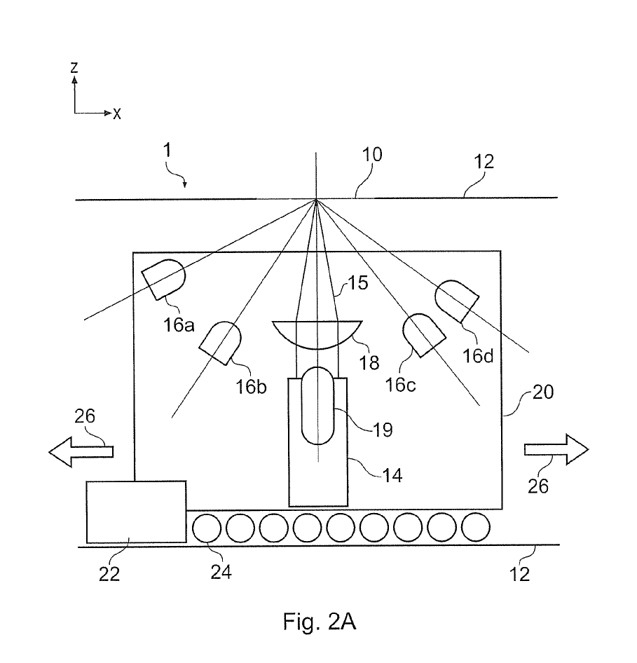

FIG. 2A shows a schematic side view of a first example of a reader apparatus 1. The optical reader apparatus 1 is for measuring a signature from an article (not shown) arranged in a reading volume of the apparatus. The reading volume is formed by a reading aperture 10 which is a slit in a housing 12. The housing 12 contains the main optical components of the apparatus. The slit has its major extent in the x direction (see inset axes in the drawing). The principal optical components are a laser source 14 for generating a coherent laser beam 15 and a detector arrangement 16 made up of a plurality of k photodetector elements, where k=4 in this example, labelled 16a, 16b, 16c and 16d. The laser beam 15 is focused by a cylindrical lens 18 into an elongate focus extending in the y direction (perpendicular to the plane of the drawing) and lying in the plane of the reading aperture. In one example reader, the elongate focus has a major axis dimension of about 2 mm and a minor axis dimension of about 40 micrometres. These optical components are contained in a subassembly 20. In the present example, the four detector elements 16a . . . d are distributed either side of the beam axis offset at different angles in an interdigitated arrangement from the beam axis to collect light scattered in reflection from an article present in the reading volume. In the present example, the offset angles are −70, −20, +30 and +50 degrees. The angles either side of the beam axis are chosen so as not to be equal so that the data points they collect are as independent as possible. All four detector elements are arranged in a common plane. The photodetector elements 16a . . . d detect light scattered from an article placed on the housing when the coherent beam scatters from the reading volume. As illustrated, the source is mounted to direct the laser beam 15 with its beam axis in the z direction, so that it will strike an article in the reading aperture at normal incidence.

Generally it is desirable that the depth of focus is large, so that any differences in the article positioning in the z direction do not result in significant changes in the size of the beam in the plane of the reading aperture. In the present example, the depth of focus is approximately 0.5 mm which is sufficiently large to produce good results where the position of the article relative to the scanner can be controlled to some extent. The parameters, of depth of focus, numerical aperture and working distance are interdependent, resulting in a well known trade off between spot size and depth of focus.

A drive motor 22 is arranged in the housing 12 for providing linear motion of the optics subassembly 20 via suitable bearings 24 or other means, as indicated by the arrows 26. The drive motor 22 thus serves to move the coherent beam linearly in the x direction over the reading aperture 10 so that the beam 15 is scanned in a direction transverse to the major axis of the elongate focus. Since the coherent beam 15 is dimensioned at its focus to have a cross-section in the xz plane (plane of the drawing) that is much smaller than a projection of the reading volume in a plane normal to the coherent beam, i.e. in the plane of the housing wall in which the reading aperture is set, a scan of the drive motor 22 will cause the coherent beam 15 to sample many different parts of the reading volume under action of the drive motor 22.

FIG. 2B is included to illustrate this sampling and is a schematic perspective view showing how the reading area is sampled n times by scanning an elongate beam across it. The sampling positions of the focused laser beam as it is scanned along the reading aperture under action of the drive is represented by the adjacent rectangles numbered 1 to n which sample an area of length ‘l’ and width ‘w’. Data collection is made so as to collect signal at each of the n positions as the drive is scanned along the slit. Consequently, a sequence of k×n data points are collected that relate to scatter from the n different illustrated parts of the reading volume.

Also illustrated schematically are optional distance marks 28 formed on the underside of the housing 12 adjacent the slit 10 along the x direction, i.e. the scan direction. An example spacing between the marks in the x-direction is 300 micrometres. These marks are sampled by a tail of the elongate focus and provide for linearisation of the data in the x direction in situations where such linearisation is required, as is described in more detail further below. The measurement is performed by an additional phototransistor 19 which is a directional detector arranged to collect light from the area of the marks 28 adjacent the slit.

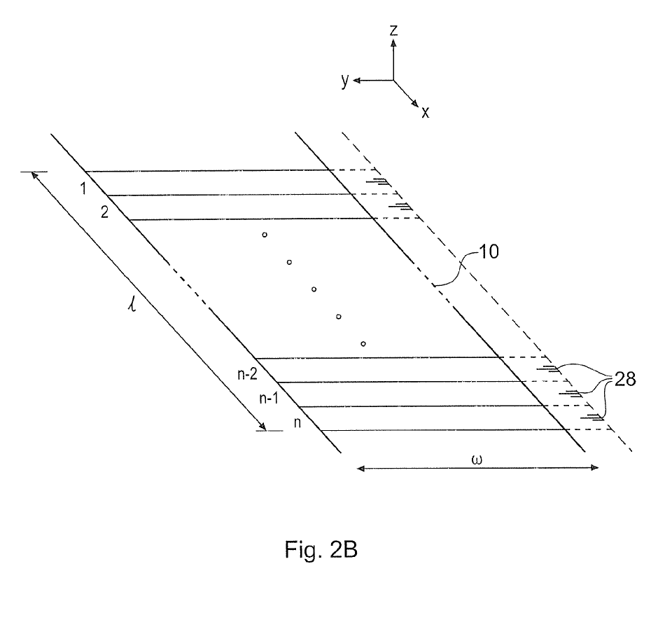

In alternative examples, the marks 28 can be read by a dedicated encoder emitter/detector module 19 that is part of the optics subassembly 20. Encoder emitter/detector modules are used in bar code readers. In one example, an Agilent HEDS-1500 module that is based on a focused light emitting diode (LED) and photodetector can be used. The module signal is fed into the PIC ADC as an extra detector channel (see discussion of FIG. 3 below).

With an example minor dimension of the focus of 40 micrometers, and a scan length in the x direction of 2 cm, n=500, giving 2000 data points with k=4. A typical range of values for k×n depending on desired security level, article type, number of detector channels ‘k’ and other factors is expected to be 100<k×n<10,000. It has also been found that increasing the number of detectors k also improves the insensitivity of the measurements to surface degradation of the article through handling, printing etc. In practice, with the prototypes used to date, a rule of thumb is that the total number of independent data points, i.e. k×n, should be 500 or more to give an acceptably high security level with a wide variety of surfaces. Other minima (either higher or lower) may apply where a scanner is intended for use with only one specific surface type or group of surface types.

FIG. 3 is a block schematic diagram of functional components of the reader apparatus. The motor 22 is connected to a programmable interrupt controller (PIC) 30 through an electrical link 23. The detectors 16a . . . d of the detector module 16 are connected through respective electrical connection lines 17a . . . d to an analogue-to-digital converter (ADC) that is part of the PIC 30. A similar electrical connection line 21 connects the marker reading detector 19 to the PIC 30. It will be understood that optical or wireless links may be used instead of, or in combination with, electrical links. The PIC 30 is interfaced with a personal computer (PC) 34 through a data connection 32. The PC 34 may be a desktop or a laptop. As an alternative to a PC, other intelligent devices may be used, for example a personal digital assistant (PDA) or a dedicated electronics unit. The PIC 30 and PC 34 collectively form a data acquisition and processing module 36 for determining a signature of the article from the set of data points collected by the detectors 16a . . . d.

The PC 34 has access through an interface connection 38 to a database (dB) 40 containing a plurality of records, one for each manufactured and tested IC. The database 40 may be resident on the PC 34 in memory, or stored on a drive thereof. Alternatively, the database 40 may be remote from the PC 34 and accessed by wireless communication, for example using mobile telephony services or a wireless local area network (LAN) in combination with the internet. Moreover, the database 40 may be stored locally on the PC 34, but periodically downloaded from a remote source. The database may be administered by a remote entity, which entity may provide access to only a part of the total database to the particular PC 34, and/or may limit access the database on the basis of a security policy.

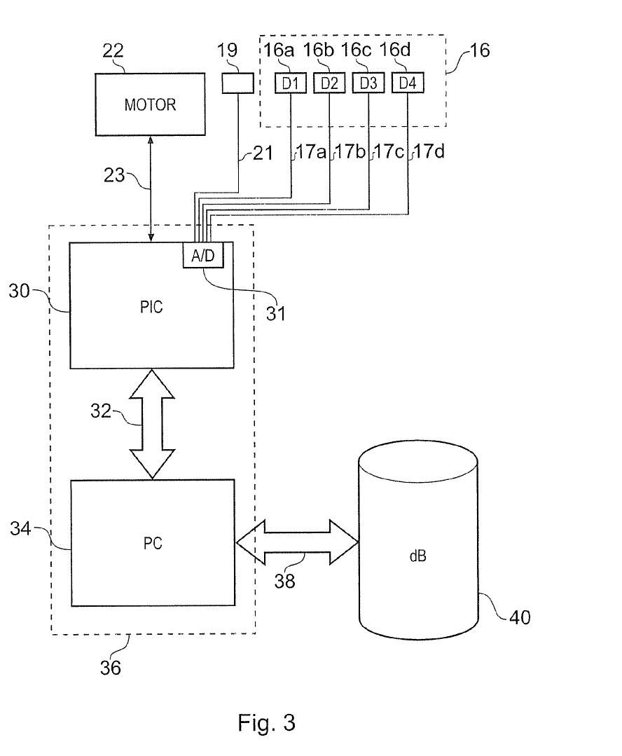

FIG. 4A shows schematically a sample record. Each record includes the recorded signature taken from the IC packaging, the originally specified clock speed (or other performance attribute) of the IC together with more general data relevant to the packaged IC, such as product type, version number, batch number and so forth. The PC 34 can be programmed so that in use it can access the database 40 and performs a comparison to establish whether the database 40 contains a match to the signature of the article that has been placed in the reading volume. The PC 34 can also be programmed to allow a signature to be added to the database if no match is found.

The way in which data flow between the PC and database is handled can be dependent upon the location of the PC and the relationship between the operator of the PC and the operator of the database. For example, if the PC and reader are being used to confirm the authenticity of an article and check the manufacturer's specified performance attribute, such as clock speed, then the PC will not need to be able to add new articles to the database, and may in fact not directly access the database, but instead provide the signature to the database for comparison. In this arrangement the database may provide an authenticity result to the PC to indicate whether the article is authentic and if authentic provide the performance specification ascribed to the article by the manufacturer. On the other hand, if the PC and reader are being used to record or validate an item within the database, then the signature can be provided to the database for storage therein, and no comparison may be needed. In this situation a comparison could be performed however, to avoid a single item being entered into the database twice.

FIG. 4B is a plan and side view of an example IC package 5 (a QFP package is shown). The lead frame pins or legs 72 are visible. In side view, the side surface above the lead frame is labelled with reference numeral 70, since this is a suitable surface portion for signature scanning as it is normally not used for conventional labelling. The upper surface 54 of the package also provides suitable candidate surface portions for the signature area. To the top left of the upper surface 54 there is a labelled area 56 which bears a machine readable mark in the form of a barcode 58 which encodes the manufacturer's performance specification for the IC, in this case specified (maximum) clock speed, as well as optionally other information. The specified (maximum) clock speed is also labelled onto this area alphanumerically in human readable form, as indicated by reference numeral 60.

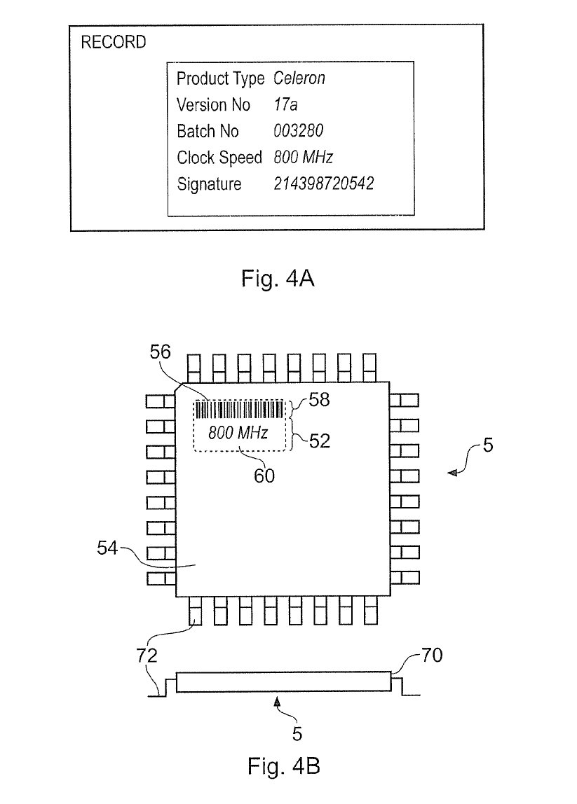

FIG. 5 is a perspective view of the reader apparatus 1 showing its external form. The housing 12 and slit-shaped reading aperture 10 are evident. A physical location aid 42 is also apparent and is provided for positioning an article of a given form in a fixed position in relation to the reading aperture 10. In the present example, the physical location aid 42 is in the form of a right-angle bracket in which the corner of an article can be located. This ensures that the same part of the article can be positioned in the reading aperture 10 whenever the article needs to be scanned. A simple angle bracket or equivalent, is sufficient for articles with a well-defined corner, such as a packaged IC. Other shaped position guides could be provided to accept different specific IC package sizes, such as rectangular locating holes.

Thus there has now been described an example of a scanning and signature generation apparatus suitable for use in a security mechanism for remote verification of article authenticity. Such a system can be deployed to allow an article to be scanned in more than one location, and for a check to be performed to ensure that the article is the same article in both instances, and for a check to be performed to ensure that the article's performance specification markings, e.g. clock speed marking, has not been tampered with between initial and subsequent scannings.

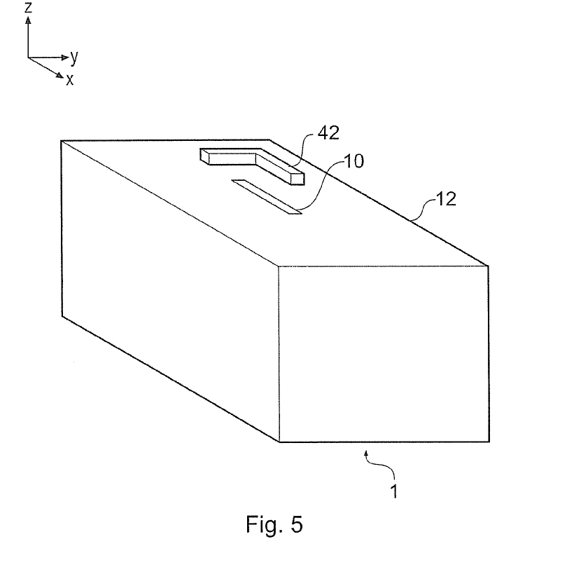

FIG. 6 is a schematic perspective view of an alternative embodiment showing a reader apparatus 1′ intended for screening batches of packaged ICs. The reader is based on a conveyor 44 shaped to carry packaged ICs, in this case in DIL/DIP package format. Three DIL packaged ICs 5 are illustrated by way of example. A reading area on the side face of the DIL package 5 is scanned by a static laser beam 15 as the article 5 passes on the conveyor 44. The laser beam 15 is generated by a laser source 14 arranged fixed in position beside the conveyor 44. The laser source 14 has an integral beam focusing lens (not shown) for producing a pencil-like near-collimated beam that travels in the z direction (i.e. horizontal to the floor) to pass over the conveyor 44 at an appropriate height for the I package dimensions. The beam cross-section may be a spot, i.e. circular (e.g. produced with integral spherical lens), or a line extending in the y direction (e.g. produced with integral cylindrical lens). A stream of packaged ICs can thus be conveyed and scanned in succession as they pass through the beam 15.

The functional components of the conveyor-based reader apparatus are similar to those of the stand-alone reader apparatus described further above. The only difference of substance is that the article is moved rather than the laser beam, in order to generate the desired relative motion between scan beam and article.

It is envisaged that the conveyor-based reader can be used in a production line or warehouse environment for populating a database with signatures by reading a succession of articles. As a control, each article may be scanned again to verify that the recorded signature can be verified. This could be done with two systems operating in series, or one system through which each article passes twice. Batch scanning could also be applied during a wholesale transaction to check the goods, or immediately prior to insertion in a motherboard or other circuit board as a quality control check.

There are thus envisaged to be two main uses of batch scanning, first to populate the product database at the time of manufacture, and second to check the authenticity of a batch of products and, for authentic articles, what the manufacturer's performance specification is, and optionally if this is consistent with the labelled performance specification.

The batch scanning may be carried out in combination with a marking machine 62 which may be a laser marking machine as illustrated in FIG. 6, a printing based device, or some other suitable machine. In the figure, a laser marker 62 is shown positioned above the packaged ICs with a steerable beam 64 for exposing the upper surface of the IC package to write in the labelled area 56 with suitable labelling which may be a combination or barcode and alphanumeric script as discussed further above.

At the time of manufacture, this may be to write the manufacturer's performance specification label on the packaged IC. Post-manufacture, this may be to write a further duplicate performance specification label on the packaged IC, or may merely be to mark the articles with something simpler, such as a coloured spot. For example, a red spot could be written onto packaged ICs that are authentic but carry forged labels, and/or a green spot on packaged ICs that are authentic and the manufacturer's performance specification label indicates the same performance specification as the labelling on the packaged IC.

The batch scanning may also be carried out in conjunction with an automated label reader. For example this may be useful post-manufacture. The performance specification label on the packaged IC may be written as a machine readable mark such as a barcode, which can then be read by a barcode reader, and this specification compared with the manufacturer's specification stored in the product database. A label reading machine capable or reading plain human-readable alphanumeric labels may also be provided.

The batch scanning may also be carried out in conjunction with an automated sorter. For example a pick and place robot with a manipulation head 66 and an arm 68 may be provided above the conveyor and may be controlled to lift out any packaged ICs that fail either the authenticity verification check or the performance specification label check. Sorting may be used instead of the result-based marking described above or in combination with such marking.

The above-described embodiments are based on localised excitation with a coherent light beam of small cross-section in combination with detectors that accept light signal scattered over a much larger area that includes the local area of excitation. It is possible to design a functionally equivalent optical system which is instead based on directional detectors that collect light only from localised areas in combination with excitation of a much larger area.

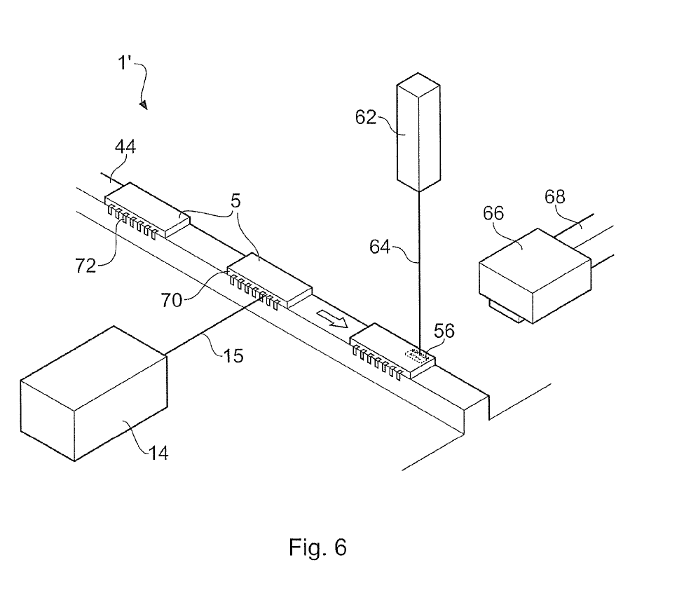

FIG. 7A shows schematically in side view such an imaging arrangement for a reader which is based on directional light collection and blanket illumination with a coherent beam. An array detector 48 is arranged in combination with a cylindrical microlens array 46 so that adjacent strips of the detector array 48 only collect light from corresponding adjacent strips in the reading volume. With reference to FIG. 2B, each cylindrical microlens is arranged to collect light signal from one of the n sampling strips. The coherent illumination can then take place with blanket illumination of the whole reading volume (not shown in the illustration).

A hybrid system with a combination of localised excitation and localised detection may also be useful in some cases.

FIG. 7B shows schematically in plan view the optical footprint of such a hybrid imaging arrangement for a reader in which directional detectors are used in combination with localised illumination with an elongate beam. This example may be considered to be a development of the example of FIG. 2A in which directional detectors are provided. In this example three banks of directional detectors are provided, each bank being targeted to collect light from different portions along the ‘l ×w’ excitation strip. The collection area from the plane of the reading volume are shown with the dotted circles, so that a first bank of, for example 2, detectors collects light signal from the upper portion of the excitation strip, a second bank of detectors collects light signal from a middle portion of the excitation strip and a third bank of detectors collects light from a lower portion of the excitation strip. Each bank of detectors is shown having a circular collection area of diameter approximately 1/m, where m is the number of subdivisions of the excitation strip, where m=3 in the present example. In this way the number of independent data points can be increased by a factor of m for a given scan length l . As described further below, one or more of different banks of directional detectors can be used for a purpose other than collecting light signal that samples a speckle pattern. For example, one of the banks may be used to collect light signal in a way optimised for barcode scanning. If this is the case, it will generally be sufficient for that bank to contain only one detector, since there will be no advantage obtaining cross-correlations when only scanning for contrast.

Having now described the principal structural components and functional components of various reader apparatuses, the numerical processing used to determine a signature will now be described. It will be understood that this numerical processing can be implemented for the most part in a computer program that runs on the PC 34 with some elements subordinated to the PIC 30. In alternative examples, the numerical processing could be performed by a dedicated numerical processing device or devices in hardware or firmware.

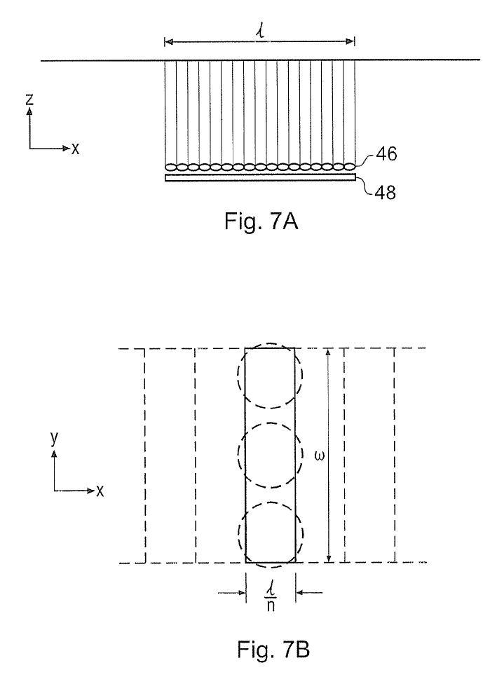

FIG. 8 shows an image for a plastic surface. This atomic force microscopy image clearly shows the uneven surface of the macroscopically smooth plastic surface. The surface undulation can be uniquely identified using the signature generation scheme described herein. Different materials will have different characteristic dimensions for the surface structure, and it is important that the dimension range for the material of interest has the correct relationship to the optical wavelength of the coherent beam to cause diffraction and hence speckle, and also diffuse scattering. It will thus be appreciated that if a reader is to be designed for a specific class of goods, the wavelength of the laser can be tailored to the structure feature size of the class of goods to be scanned. In the present context, this means the reader design may be different depending on what parts of the IC packaging are chosen to provide the scan surface. As will be appreciated, surface portions of IC packaging will usually comprise a mixture of several of ceramic, metals, plastics compounds, and epoxy, and in principle the surface portion could be selected to be from any one of these materials, or perhaps more than one in some cases.

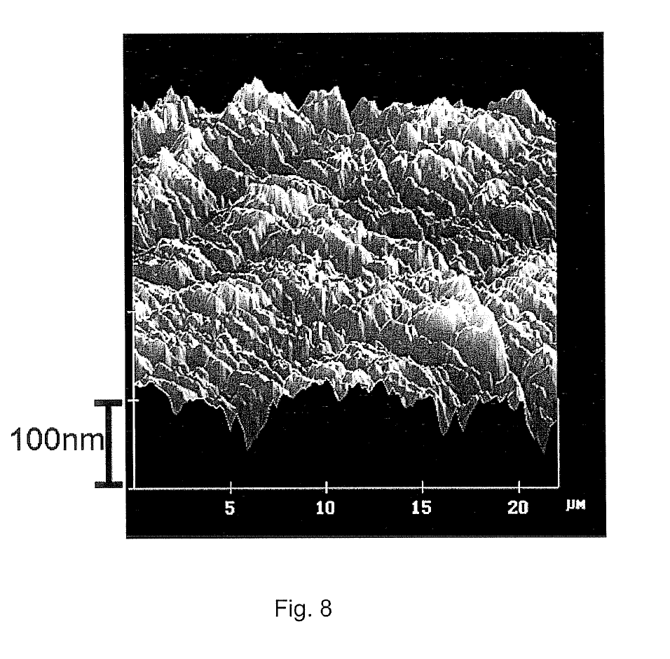

FIG. 9A shows raw data from a single one of the photodetectors 16a . . . d of the reader of FIG. 2A. The graph plots signal intensity I in arbitrary units (a.u.) against point number n (see FIG. 2B). The higher trace fluctuating between I=0-250 is the raw signal data from photodetector 16a. The lower trace is the encoder signal picked up from the markers 28 (see FIG. 2B) which is at around I=50.

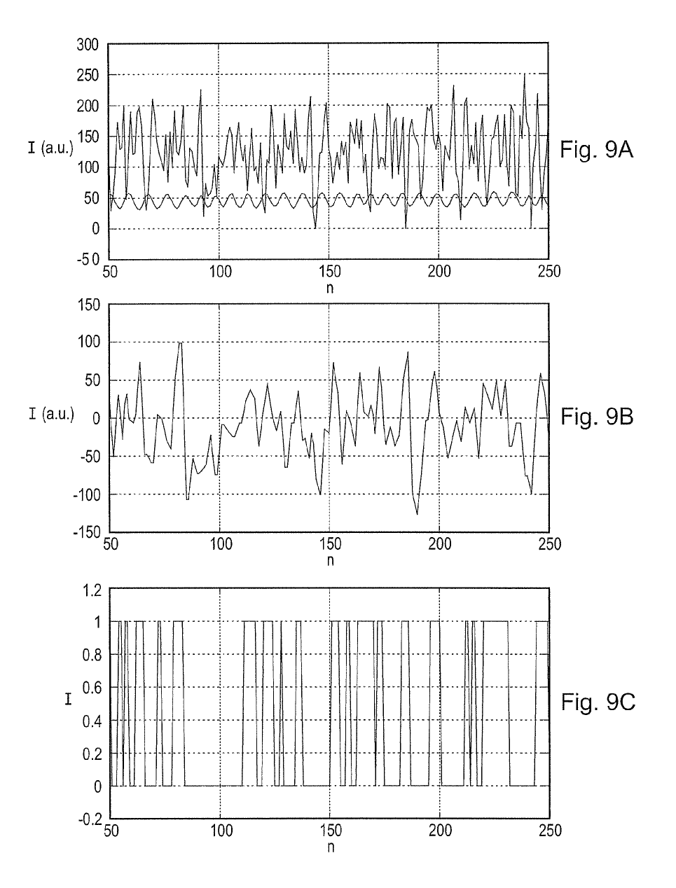

FIG. 9B shows the photodetector data of FIG. 10A after linearisation with the encoder signal (n.b. although the x axis is on a different scale from FIG. 10A, this is of no significance). As noted above, where a movement of the article relative to the scanner is sufficiently linear, there may be no need to make use of a linearisation relative to alignment marks. In addition, the average of the intensity has been computed and subtracted from the intensity values. The processed data values thus fluctuate above and below zero.

FIG. 9C shows the data of FIG. 9B after digitisation. The digitisation scheme adopted is a simple binary one in which any positive intensity values are set at value 1 and any negative intensity values are set at zero. It will be appreciated that multi-state digitisation could be used instead, or any one of many other possible digitisation approaches. The main important feature of the digitisation is merely that the same digitisation scheme is applied consistently.

FIG. 10 is a flow diagram showing how a signature of an article is generated from a scan.

Step S1 is a data acquisition step during which the optical intensity at each of the photodetectors is acquired approximately every 1 ms during the entire length of scan. Simultaneously, the encoder signal is acquired as a function of time. It is noted that if the scan motor has a high degree of linearisation accuracy (e.g. as would a stepper motor) then linearisation of the data may not be required. The data is acquired by the PIC 30 taking data from the ADC 31. The data points are transferred in real time from the PIC 30 to the PC 34. Alternatively, the data points could be stored in memory in the PIC 30 and then passed to the PC 34 at the end of a scan. The number n of data points per detector channel collected in each scan is defined as N in the following. Further, the value aₖ(i) is defined as the i-th stored intensity value from photodetector k, where i runs from 1 to N. Examples of two raw data sets obtained from such a scan are illustrated in FIG. 9A.

Step S2 uses numerical interpolation to locally expand and contract aₖ(i) so that the encoder transitions are evenly spaced in time. This corrects for local variations in the motor speed. This step can be performed in the PC 34 by a computer program.

Step S3 is an optional step. If performed, this step numerically differentiates the data with respect to time. It may also be desirable to apply a weak smoothing function to the data. Differentiation may be useful for highly structured surfaces, as it serves to attenuate uncorrelated contributions from the signal relative to correlated (speckle) contributions.

Step S4 is a step in which, for each photodetector, the mean of the recorded signal is taken over the N data points. For each photodetector, this mean value is subtracted from all of the data points so that the data are distributed about zero intensity. Reference is made to FIG. 9B which shows an example of a scan data set after linearisation and subtraction of a computed average.

Step S5 digitises the analogue photodetector data to compute a digital signature representative of the scan. The digital signature is obtained by applying the rule: aₖ(i)>0 maps onto binary ‘1’ and aₖ(i)<=0 maps onto binary ‘0’. The digitised data set is defined as dₖ(i) where i runs from 1 to N. The signature of the article may incorporate further components in addition to the digitised signature of the intensity datajust described. These further optional signature components are now described.

Step S6 is an optional step in which a smaller ‘thumbnail’ digital signature is created. This is done either by averaging together adjacent groups of m readings, or more preferably by picking every cth data point, where c is the compression factor of the thumbnail. The latter is preferred since averaging may disproportionately amplify noise. The same digitisation rule used in Step S5 is then applied to the reduced data set. The thumbnail digitisation is defined as tₖ(i) where i runs 1 to N/c and c is the compression factor.

Step S7 is an optional step applicable when multiple detector channels exist. The additional component is a cross-correlation component calculated between the intensity data obtained from different ones of the photodetectors. With 2 channels there is one possible cross-correlation coefficient, with 3 channels up to 3, and with 4 channels up to 6 etc. The cross-correlation coefficients are useful, since it has been found that they are good indicators of material type. For example, for a particular type of article, such as an IC of a given packaging type, the cross-correlation coefficients can be expected to lie in predictable ranges. A normalised cross-correlation can be calculated between aₖ(i) and aₗ(i), where k≢l and k,l vary across all of the photodetector channel numbers. The normalised cross-correlation function Γ is defined as

$$Γ ( k , l ) = \frac{{\sum }_{i = 1}^{N} {a}_{k} ( i ) {a}_{l} ( i )}{\sqrt{( {\sum }_{i = 1}^{N} {{a}_{k} ( i )}^{2} ) ( {\sum }_{i = 1}^{N} {{a}_{l} ( i )}^{2} )}}$$

Another aspect of the cross-correlation function that can be stored for use in later verification is the width of the peak in the cross-correlation function, for example the full width half maximum (FWHM). The use of the cross-correlation coefficients in verification processing is described further below.

Step S8 is another optional step which is to compute a simple intensity average value indicative of the signal intensity distribution. This may be an overall average of each of the mean values for the different detectors or an average for each detector, such as a root mean square (rms) value of aₖ(i). If the detectors are arranged in pairs either side of normal incidence as in the reader described above, an average for each pair of detectors may be used. The intensity value has been found to be a good crude filter for material type, since it is a simple indication of overall reflectivity and roughness of the sample. For example, one can use as the intensity value the unnormalised rms value after removal of the average value, i.e. the DC background.

The signature data obtained from scanning an article can be compared against records held in a signature database for verification purposes and/or written to the database to add a new record of the signature to extend the existing database.

A new database record will include the digital signature obtained in Step S5. This can optionally be supplemented by one or more of its smaller thumbnail version obtained in Step S6 for each photodetector channel, the cross-correlation coefficients obtained in Step S7 and the average value(s) obtained in Step S8. Alternatively, the thumbnails may be stored on a separate database of their own optimised for rapid searching, and the rest of the data (including the thumbnails) on a main database.

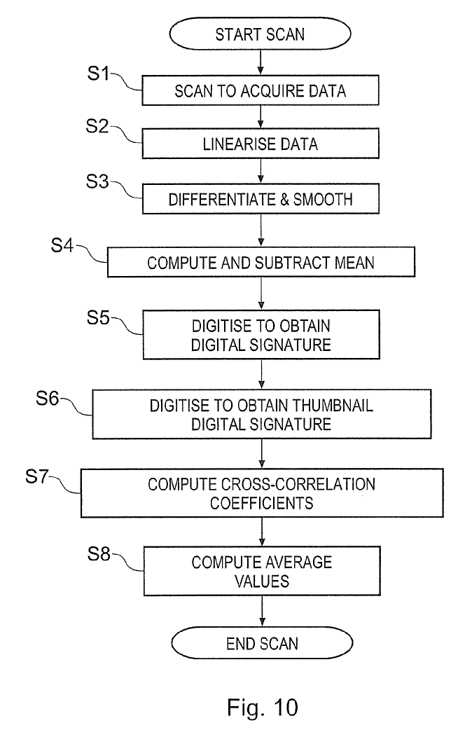

FIG. 11 is a flow diagram showing how a signature of an article obtained from a scan can be verified against a signature database.

In a simple implementation, the database could simply be searched to find a match based on the full set of signature data. However, to speed up the verification process, the process can use the smaller thumbnails and pre-screening based on the computed average values and cross-correlation coefficients as now described.

Verification Step V1 is the first step of the verification process, which is to scan an article according to the process described above, i.e. to perform Scan Steps S1 to S8.

Verification Step V2 takes each of the thumbnail entries and evaluates the number of matching bits between it and tₖ(i+j), where j is a bit offset which is varied to compensate for errors in placement of the scanned area. The value of j is determined and then the thumbnail entry which gives the maximum number of matching bits. This is the ‘hit’ used for further processing.

Verification Step V3 is an optional pre-screening test that is performed before analysing the full digital signature stored for the record against the scanned digital signature. In this pre-screen, the rms values obtained in Scan Step S8 are compared against the corresponding stored values in the database record of the hit. The ‘hit’ is rejected from further processing if the respective average values do not agree within a predefined range. The article is then rejected as non-verified (i.e. jump to Verification Step V6 and issue fail result).

Verification Step V4 is a further optional pre-screening test that is performed before analysing the full digital signature. In this pre-screen, the cross-correlation coefficients obtained in Scan Step S7 are compared against the corresponding stored values in the database record of the hit. The ‘hit’ is rejected from further processing if the respective cross-correlation coefficients do not agree within a predefined range. The article is then rejected as non-verified (i.e. jump to Verification Step V6 and issue fail result).

Another check using the cross-correlation coefficients that could be performed in Verification Step V4 is to check the width of the peak in the cross-correlation function, where the cross-correlation function is evaluated by comparing the value stored from the original scan in Scan Step S7 above and the re-scanned value:

$${Γ}_{k , l} ( j ) = \frac{{\sum }_{i = 1}^{N} {a}_{k} ( i ) {a}_{l} ( i + j )}{\sqrt{( {\sum }_{i = 1}^{N} {{a}_{k} ( i )}^{2} ) ( {\sum }_{i = 1}^{N} {{a}_{l} ( i )}^{2} )}}$$

If the width of the re-scanned peak is significantly higher than the width of the original scan, this may be taken as an indicator that the re-scanned article has been tampered with or is otherwise suspicious. For example, this check should beat a fraudster who attempts to fool the system by printing a bar code or other pattern with the same intensity variations that are expected by the photodetectors from the surface being scanned.

Verification Step V5 is the main comparison between the scanned digital signature obtained in Scan Step S5 and the corresponding stored values in the database record of the hit. The full stored digitised signature, dₖ^{db}(i) is split into n blocks of q adjacent bits on k detector channels, i.e. there are qk bits per block. A typical value for q is 4 and a typical value for k is 4, making typically 16 bits per block. The qk bits are then matched against the qk corresponding bits in the stored digital signature dₖ^{db}(i+j). If the number of matching bits within the block is greater or equal to some pre-defined threshold Zₜₕᵣₑₛₕ, then the number of matching blocks is incremented. A typical value for Zₜₕᵣₑₛₕ is 13. This is repeated for all n blocks. This whole process is repeated for different offset values of j, to compensate for errors in placement of the scanned area, until a maximum number of matching blocks is found. Defining M as the maximum number of matching blocks, the probability of an accidental match is calculated by evaluating:

$$p ( M ) = {\sum }_{w = n - M}^{n} {{s}^{w} ( 1 - s )}^{n - w} {}_{w}^{n} C$$

where s is the probability of an accidental match between any two blocks (which in turn depends upon the chosen value of Z_{threshold}), M is the number of matching blocks and p(M) is the probability of M or more blocks matching accidentally. The value of s is determined by comparing blocks within the data base from scans of different objects of similar materials, e.g. a number of scans of paper documents etc. For the case of q=4, k=4 and Z_{threshold}=13, we typical value of s is 0.1. If the qk bits were entirely independent, then probability theory would give s=0.01 for Z_{threshold}=13. The fact that a higher value is found empirically is because of correlations between the k detector channels and also correlations between adjacent bits in the block due to a finite laser spot width. A typical scan of a piece of paper yields around 314 matching blocks out of a total number of 510 blocks, when compared against the data base entry for that piece of paper. Setting M=314, n=510, s=0.1 for the above equation gives a probability of an accidental match of 10⁻¹⁷⁷.

Verification Step V6 issues a result of the verification process. The probability result obtained in Verification Step V5 may be used in a pass/fail test in which the benchmark is a pre-defined probability threshold. In this case the probability threshold may be set at a level by the system, or may be a variable parameter set at a level chosen by the user. Alternatively, the probability result may be output to the user as a confidence level, either in raw form as the probability itself, or in a modified form using relative terms (e.g. no match/poor match/good match/excellent match) or other classification.

It will be appreciated that many variations are possible. For example, instead of treating the cross-correlation coefficients as a pre-screen component, they could be treated together with the digitised intensity data as part of the main signature. For example the cross-correlation coefficients could be digitised and added to the digitised intensity data. The cross-correlation coefficients could also be digitised on their own and used to generate bit strings or the like which could then be searched in the same way as described above for the thumbnails of the digitised intensity data in order to find the hits.

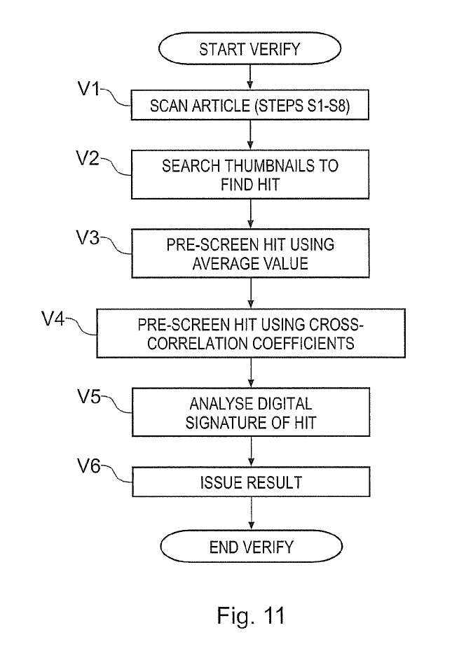

FIG. 12 is a flow diagram showing how the performance specification of a packaged IC is checked according to an embodiment of the invention.

In Step L1, the authenticity verification process of FIG. 11 is carried out. If the scanned signature from the IC package is not recognised (NO result), i.e. no match is found in the product database, then the flow proceeds to Step L7 and an output of “IC not recognised” is given. If the scanned signature from the IC package is recognised (YES result), i.e. a match is found in the product database, then the IC is identified as originating from the manufacturer and the flow proceeds to Step L2.

In Step L2, the performance specification, e.g. clock speed, is looked up in the database record with the matching signature.

In Step L3, the specification marked on the product by its label is input. This may be a manual input, for example if there is a test of only one packaged IC being carried out by the manufacturer as part of a warranty claim. On the other hand, it may be an automatic input, for example through an automated label reader, such as a barcode reader.

In Step L4, the label is verified by comparing the labelled specification with the manufacturer's specification retrieved from the product database. If these match (YES result), then the flow proceeds to Step L5 to output a “label OK” result. If they do not match, then the flow proceeds to Step L6 to output a “label forged” result.

The outputs from Steps L5, L6 and L7 may be visual outputs to an operator, and/or internal logic outputs used by subsequent computer-implemented processing steps. The outputs may be used to control apparatus, such as the marker or sorter discussed in connection with FIG. 6 above.

An improvement on the verification process is now described.

An article may appear to a scanner to be stretched or shrunk if the relative speed of the article to the sensors in the scanner is non-linear. This may occur if, for example the article is being moved along a conveyor system, or if the article is being moved through a scanner by a human holding the article.

As described above, where a scanner is based upon a scan head which moves within the scanner unit relative to an article held stationary against or in the scanner, then linearisation guidance can be provided by the optional distance marks 28 to address any non-linearities in the motion of the scan head. Where the article is moved by a human, these non-linearities can be greatly exaggerated

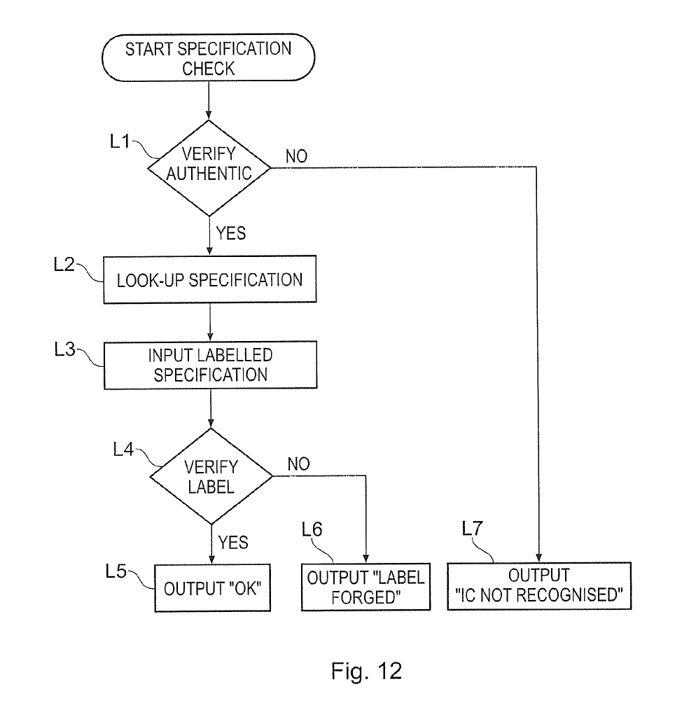

To address recognition problems which could be caused by these non-linear effects, it is possible to adjust the analysis phase of a scan of an article. Thus a modified validation procedure will now be described with reference to FIG. 13. The process implemented in this example uses a block-wise analysis of the data to address the non-linearities.

The process carried out in accordance with FIG. 13, can include some or all of the steps of smoothing and differentiating the data, computing and subtracting the mean, and digitisation for obtaining the signature and thumbnail described with reference to FIG. 10, but are not shown in FIG. 13 so as not to obscure the content of that figure.

As shown in FIG. 13, the scanning process for a validation scan using a block-wise analysis starts at step S21 by performing a scan of the article to acquire the date describing the intrinsic properties of the article. This scanned data is then divided into contiguous blocks (which can be performed before or after digitisation and any smoothing/differentiation or the like) at step S22. In one example, a scan length of 64 mm is divided into eight equal length blocks. Each block therefore represents a subsection of scanned area of the scanned article.

For each of the blocks, a cross-correlation is performed against the equivalent block for each stored signature with which it is intended that article be compared at step S23. This can be performed using a thumbnail approach with one thumbnail for each block. The results of these cross-correlation calculations are then analysed to identify the location of the cross-correlation peak. The location of the cross-correlation peak is then compared at step S24 to the expected location of the peak for the case were a perfectly linear relationship to exist between the original and later scans of the article.

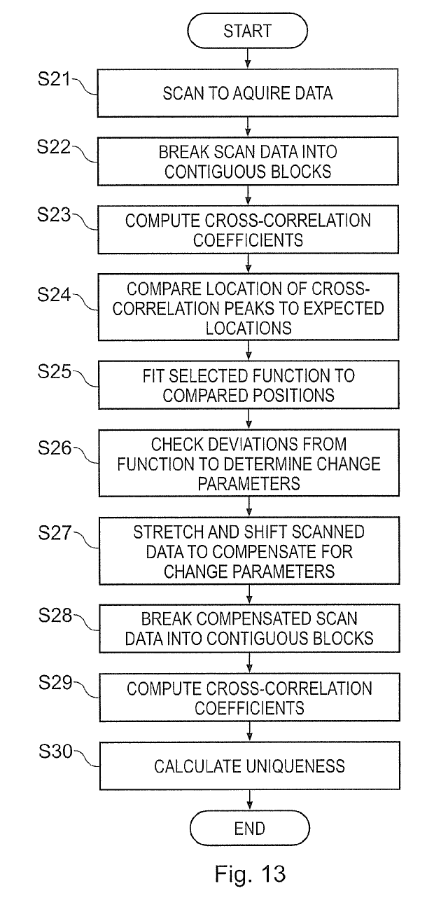

This relationship can be represented graphically as shown in FIGS. 14A, 14B and 14C. In the example of FIG. 14A, the cross-correlation peaks are exactly where expected, such that the motion of the scan head relative to the article has been perfectly linear and the article has not experienced stretch or shrinkage. Thus a plot of actual peak positions against expected peak results in a straight line which passes through the origin and has a gradient of 1.

In the example of FIG. 14B, the cross-correlation peaks are closer together than expected, such that the gradient of a line of best fit is less than one. Thus the article has shrunk relative to its physical characteristics upon initial scanning. Also, the best fit line does not pass through the origin of the plot. Thus the article is shifted relative to the scan head compared to its position upon initial scanning.

In the example of FIG. 14C, the cross correlation peaks do not form a straight line. In this example, they approximately fit to a curve representing a y² function. Thus the movement of the article relative to the scan head has slowed during the scan. Also, as the best fit curve does not cross the origin, it is clear that the article is shifted relative to its position upon initial scanning.

A variety of functions can be test-fitted to the plot of points of the cross-correlation peaks to find a best-fitting function. Thus curves to account for stretch, shrinkage, misalignment, acceleration, deceleration, and combinations thereof can be used. Examples of suitable functions can include straight line functions, exponential functions, a trigonometric functions, x² functions and x³ functions.

Once a best-fitting function has been identified at step S25, a set of change parameters can be determined which represent how much each cross-correlation peak is shifted from its expected position at step S26. These compensation parameters can then, at step S27, be applied to the data from the scan taken at step S21 in order substantially to reverse the effects of the shrinkage, stretch, misalignment, acceleration or deceleration on the data from the scan. As will be appreciated, the better the best-fit function obtained at step S25 fits the scan data, the better the compensation effect will be.

The compensated scan data is then broken into contiguous blocks at step S28 as in step S22. The blocks are then individually cross-correlated with the respective blocks of data from the stored signature at step S29 to obtain the cross-correlation coefficients. This time the magnitude of the cross-correlation peaks are analysed to determine the uniqueness factor at step S29. Thus it can be determined whether the scanned article is the same as the article which was scanned when the stored signature was created.

Accordingly, there has now been described an example of a method for compensating for physical deformations in a scanned article, and for non-linearities in the motion of the article relative to the scanner. Using this method, a scanned article can be checked against a stored signature for that article obtained from an earlier scan of the article to determine with a high level of certainty whether or not the same article is present at the later scan. Thereby an article that has been distorted can be reliably recognised. Also, a scanner where the motion of the scanner relative to the article may be non-linear can be used, thereby allowing the use of a low-cost scanner without motion control elements.

Another characteristic of an article which can be detected using a block-wise analysis of a signature generated based upon an intrinsic property of that article is that of localised damage to the article. For example, such a technique can be used to detect modifications to an article made after an initial record scan.

In the general case a test for authenticity of an article can comprise a test for a sufficiently high quality match between a verification signature and a record signature for the whole of the signature, and a sufficiently high match over at least selected blocks of the signatures. Thus regions important to the assessing the authenticity of an article can be selected as being critical to achieving a positive authenticity result.

In some examples, blocks other than those selected as critical blocks may be allowed to present a poor match result. Thus a document may be accepted as authentic despite being torn or otherwise damaged in parts, so long as the critical blocks provide a good match and the signature as a whole provides a good match.

In some scanner apparatuses, it is also possible that it may be difficult to determine where a scanned region starts and finishes. Of the examples discussed above, this is most problematic for the example of FIG. 6B, where an article to be scanned passes through a slot, such that the scan head may “see” more of an article than the intended scan area. One approach to addressing this difficulty would be to define the scan area as starting at the edge of the article. As the data received at the scan head will undergo a clear step change when an article is passed though what was previously free space, the data retrieved at the scan head can be used to determine where the scan starts.

An example of this would be when a batch of ICs is to be purchased, and the would-be purchaser uses a conveyor scanner to check the authenticity of the IC batch, and the performance specifications of the ICs in the batch. For example, if the ICs are processors being offered as 1 GHz clock speed, then the check will be one to verify that this is indeed the clock speed ascribed to these ICs by the manufacturer. In this respect, it is noted that the clock speed markings on the ICs need not be referred to, since they are in some way irrelevant. In other words, the would-be buyer is not interested as such in whether the clock speed marking have been forged, only in the true clock speed specification of the ICs. On the other hand, if the scanning was being done by a law enforcement agency, for example at a port of entry, then it would be directly relevant to ascertain whether the manufacturer's specification differs from the specification indicated by the current marking, since this would indicate that a forgery has taken place. Other parties interested in testing batches of ICs could be any party in the distribution chain, including wholesalers, distributors, and companies that populate boards with the ICs.

In this example, the scan head is operational prior to the application of the article to the scanner. Thus initially the scan head receives data corresponding to the unoccupied space in front of the scan head. As the article is passed in front of the scan head, the data received by the scan head immediately changes to be data describing the article. Thus the data can be monitored to determine where the article starts and all data prior to that can be discarded. The position and length of the scan area relative to the article leading edge can be determined in a number of ways. The simplest is to make the scan area the entire length of the article, such that the end can be detected by the scan head again picking up data corresponding to free space. Another method is to start and/or stop the recorded data a predetermined number of scan readings from the leading edge. Assuming that the article always moves past the scan head at approximately the same speed, this would result in a consistent scan area. Another alternative is to use actual marks on the article to start and stop the scan region, although this may require more work, in terms of data processing, to determine which captured data corresponds to the scan area and which data can be discarded.

Thus there has now been described an number of techniques for scanning an item to gather data based on an intrinsic property of the article, compensating if necessary for damage to the article or non-linearities in the scanning process, and comparing the article to a stored signature based upon a previous scan of an article to determine whether the same article is present for both scans.

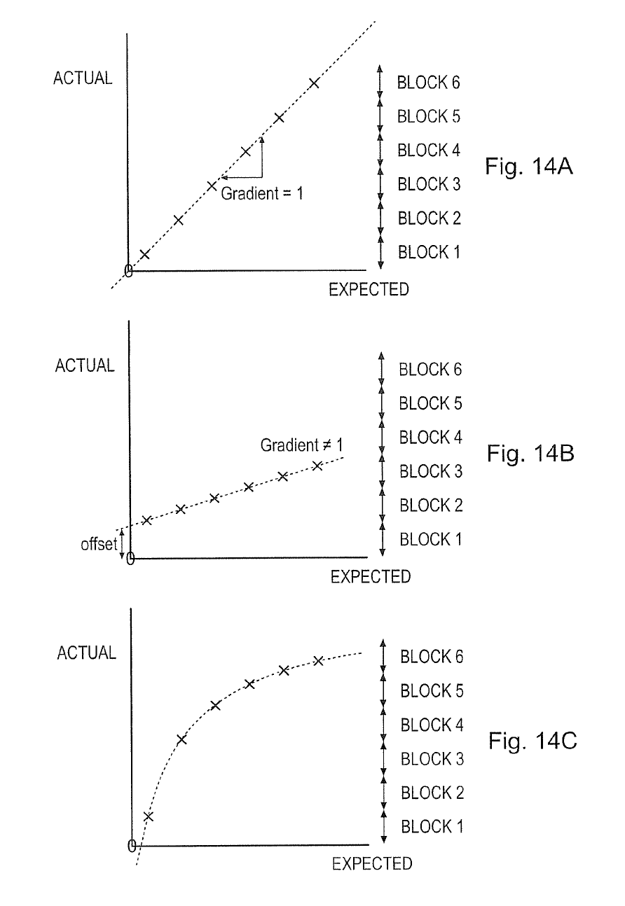

FIG. 15 shows a multi-scan head signature generation apparatus for database creation.

As shown in FIG. 15, a reader unit 100 can include two optic subassemblies 20, each operable to create a signature for an article presented in a reading volume 102 of the reader unit. Thus an item presented for scanning to create a signature for recording of the item in an item database against which the item can later be verified, can be scanned twice, to create two signatures, spatially offset from one another by a likely alignment error amount. Thus a later scan of the item for identification or authenticity verification can be matched against both stored signatures. In some examples, a match against one of the two stored signatures can be considered as a successful match.

In some examples, further read heads can be used, such that three, four or more signatures are created for each item. Each scan head can be offset from the others in order to provide signatures from positions adjacent the intended scan location. Thus greater robustness to article misalignment on verification scanning can be provided.

The offset between scan heads can be selected dependent upon factors such as a width of scanned portion of the article, size of scanned are relative to the total article size, likely misalignment amount during verification scanning, and article material.

Thus there has now been described a system for scanning an article to create a signature database against which an article can be checked to verify the identity and/or authenticity of the article.

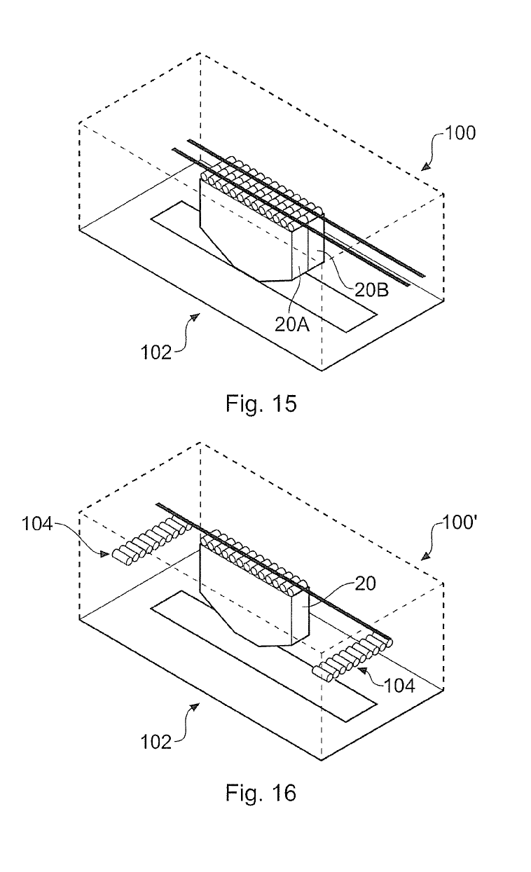

An example of another system for providing multiple signatures in an article database will now be describe with reference to FIG. 16.

As shown in FIG. 16, a reader unit 100′ can have a single optic subassembly 20 and an alignment adjustment unit 104. In use, the alignment adjustment unit 104 can alter the alignment of the optics subassembly 20 relative to the reading volume 102 of the reader unit. Thus an article placed in the reading volume can be scanned multiple times by the optics subassembly 20 in different positions so as to create multiple signatures for the article. In the present example, the alignment adjustment unit 104 can adjust the optics subassembly to read from two different locations. Thus a later scan of the item for identification or authenticity verification can be matched against both stored signatures. In some examples, a match against one of the two stored signatures can be considered as a successful match.

In some examples, further read head positions can be used, such that three, four or more signatures are created for each item. Each scan head position can be offset from the others in order to provide signatures from positions adjacent the intended scan location. Thus greater robustness to article misalignment on verification scanning can be provided.

The offset between scan head positions can be selected dependent upon factors such as a width of scanned portion of the article, size of scanned are relative to the total article size, likely misalignment amount during verification scanning, and article material.

Thus there has now been described another example of a system for scanning an article to create a signature database against which an article can be checked to verify the identity and/or authenticity of the article.

Although it has been described above that a scanner used for record scanning (i.e. scanning of articles to create reference signatures against which the article can later be validated) can use multiple scan heads and/or scan head positions to create multiple signatures for an article, it is also possible to use a similar system for later validation scanning.

For example, a scanner for use in a validation scan may have multiple read heads to enable multiple validation scan signatures to be generated. Each of these multiple signatures can be compared to a database of recorded signatures, which may itself contain multiple signatures for each recorded item. Due to the fact that, although the different signatures for each item may vary these signatures will all still be extremely different to any signatures for any other items, a match between any one record scan signature and any one validation scan signature should provide sufficient confidence in the identity and/or authenticity of an item.

A multiple read head validation scanner can be arranged much as described with reference to FIG. 15 above. Likewise, a multiple read head position validation scanner can be arranged much as described with reference to FIG. 16 above. Also, for both the record and validation scanners, a system of combined multiple scan heads and multiple scan head positions per scan head can be combined into a single device.

Although the embodiments above have been described in considerable detail, numerous variations and modifications will become apparent to those skilled in the art once the above disclosure is fully appreciated. It is intended that the following claims be interpreted to embrace all such variations and modifications as well as their equivalents.

### REFERENCES

1. GB 2 221 870 A-Ezra, Hare & Pugsley
2. U.S. Pat. No. 6,584,214-Pappu, Gershenfeld & Smith
3. JP 2000-149087-Hasegawa et al
4. WO 2005/088533-Cowburn

1. A method for creating a product database for storing a record for each of a plurality of products, the products being packaged integrated circuits, the method comprising:
providing an integrated circuit that has been attached to a package;
providing a performance attribute for the integrated circuit that has been determined from testing of the integrated circuit;
exposing a surface portion of the packaged integrated circuit to coherent radiation;
collecting a set of data points that measure scatter of the coherent radiation from the surface portion;
determining a signature from the set of data points; and
augmenting the product database by storing the signature from the package together with the performance attribute in the record for that product.

2. The method of claim 1, wherein the performance attribute is clock speed.

3. The method of claim 1, wherein the surface portion is made of a ceramic material.

4. The method of claim 1, wherein the surface portion is made of a metal.

5. The method of claim 1, wherein the surface portion is made of a plastics compound.

6. The method of claim 1, wherein the surface portion is made of an epoxy compound.

7. The method of claim 1, wherein the testing of the integrated circuit used to determine the performance attribute is carried out at least in part prior to packaging the integrated circuit.

8. The method of claim 1, wherein said exposing and collecting is performed by conveying successive packaged integrated circuits past a beam of the coherent radiation.

9. A method of determining a performance attribute of an integrated circuit ascribed to it at the time of manufacture as a result of testing, comprising:
exposing a surface portion of the packaged integrated circuit to coherent radiation;
collecting a set of data points that measure scatter of the coherent radiation from the surface portion;
determining a signature from the set of data points;
accessing a product database comprising a plurality of records of packaged integrated circuits, each record containing a signature obtained from a corresponding surface portion of the packaged integrated circuit at the time of manufacture together with the performance attribute;
locating in the database a record for the packaged integrated circuit to be verified based on comparison between the determined signature and the signatures stored in the product database; and
outputting the performance attribute of the packaged integrated circuit to be verified.

10. The method of claim 9, further comprising:
inputting the performance attribute of the packaged integrated circuit as shown by readable marks on the packaged integrated circuit; and
determining if the performance attribute indicated by the readable marks is the same as the performance attribute according to the product database as a test of whether the readable marks are forgeries.

11. The method of claim 10, wherein the readable marks are machine readable marks.

12. The method of claim 10, wherein the readable marks are human readable marks.
